(19) United States
(12) Patent Application Publication
(10) Pub. No.: US 2026/0247661 A1
(43) Pub. Date: Aug. 20, 2026

(54) Power Semiconductor Device and Method of Producing a Power Semiconductor Device

(71) Applicant: Infineon Technologies AG, Neubiberg (DE)

(72) Inventors: Hans-Jürgen Thees, Dresden (DE); Tobias Nardmann, Dresden (DE)

(21) Appl. No.: 19/532,597

(22) Filed: Feb. 6, 2026

(30) Foreign Application Priority Data
Feb. 17, 2025 (DE) 102025105910.1

(51) Int. Cl. H10D 30/66; H10D 12/00; H10D 12/01; H10D 30/01; H10D 62/10; H10D 64/66

(52) U.S. Cl. CPC H10D 30/668; H10D 12/035; H10D 12/038; H10D 12/415; H10D 12/481; H10D 30/0295; H10D 30/0297; H10D 30/665; H10D 62/107; H10D 62/116; H10D 64/675

(57) ABSTRACT

A power semiconductor device includes: trenches extending from a front side of a semiconductor body along a vertical direction into the semiconductor body; mesas formed by portions of the semiconductor body laterally confined by the trenches; first contacts electrically connecting the mesas; second contacts electrically connecting trench electrodes; and at least one of: first spacer pairs each associated with one of the mesas and arranged: above both the mesa and the trench electrodes adjacent to the mesa; adjacent to one of the first contacts electrically connecting the mesa; and between the trench insulators of the trenches adjacent to the mesa; and/or second spacer pairs each associated with one of the trench electrodes and arranged: above both the trench electrode and the adjacent mesas; adjacent to one of the second contacts electrically connecting the trench electrode; and between portions of the trench insulator isolating the trench electrode from the semiconductor body.

### TECHNICAL FIELD

This specification refers to embodiments of a power semiconductor device and to embodiments of a method of producing a power semiconductor device. The power semiconductor device has, at a front side, a trench-mesa-pattern. Embodiments described herein relate to a technique of contacting electrodes within the trenches and/or mesas between the trenches.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device comprises a semiconductor body configured to conduct a forward load current along a load current path between two load terminals of the device. The load current is conducted by means of an active region of the power semiconductor device. The active region is surrounded by an edge termination region, which is terminated by an edge of the chip.

In case of a controllable power semiconductor device, e.g., a transistor, the load current path may be controlled by means of insulated electrodes, commonly referred to as gate electrodes. For example, upon receiving a corresponding control signal, e.g., from a driver unit and via a control terminal of the device, the control electrodes may set the power semiconductor device in one of a forward conducting state and a forward blocking state.

Furthermore, some devices provide for reverse load current capability; i.e., the active region of the semiconductor body is further configured to conduct a reverse load current along a reverse load current path between the two load terminals of the device. For example, the RC (Reverse Current) IGBT is one representative of such devices. In an RC IGBT, a single chip unites an IGBT structure and a diode structure.

Often, such aforementioned power semiconductor device exhibits, at the front side of the semiconductor body, a trench-mesa-pattern. A typical challenge associated with such structure is to reliably connect the mesas with a load terminal of the power semiconductor device and/or to reliably connect trench electrodes with the load terminal or the control terminal or another terminal, in particular in case of small trench widths and/or small mesa widths.

### SUMMARY

According to an embodiment, a power semiconductor device comprises: a semiconductor body including a drift region of a first conductivity type arranged between a front side and a back side of the semiconductor body; a first load terminal at the front side and a second load terminal at the back side, wherein the semiconductor body is configured to conduct a load current along a vertical direction between the first load terminal and the second load terminal; a plurality of trenches extending from the front side along the vertical direction into the semiconductor body; a plurality of mesas formed by portions of the semiconductor body laterally confined by the plurality of trenches. Each trench includes a trench electrode; and a trench insulator isolating the trench electrode from the semiconductor body, wherein a portion of the trench insulator extends above both the trench electrode and the adjacent mesa. The power semiconductor device further comprises a plurality of first contacts electrically connecting the mesas; a plurality of second contacts electrically connecting the trench electrodes; and at least one of the following: (i) a plurality of first spacer pairs, wherein each first spacer pair is associated with one of the mesas and arranged: above both the mesa and the trench electrodes adjacent to the mesa; adjacent to one of the first contacts electrically connecting the mesa; and between the trench insulators of the trenches adjacent to the mesa; and/or (ii) a plurality of second spacer pairs, wherein each second spacer pair is associated with one of the trench electrodes and arranged: above both the trench electrode and the adjacent mesas; adjacent to one of the second contacts electrically connecting the trench electrode; and between portions of the trench insulator isolating the trench electrode from the semiconductor body.

According to another embodiment, a method of producing a power semiconductor device comprises forming the following components: a semiconductor body including a drift region of a first conductivity type arranged between a front side and a back side of the semiconductor body; a first load terminal at the front side and a second load terminal at the back side, wherein the semiconductor body is configured to conduct a load current along a vertical direction between the first load terminal and the second load terminal; a plurality of trenches extending from the front side along the vertical direction into the semiconductor body; a plurality of mesas formed by portions of the semiconductor body laterally confined by the plurality of trenches. Each trench includes a trench electrode; and a trench insulator isolating the trench electrode from the semiconductor body, wherein a portion of the trench insulator extends above both the trench electrode and the adjacent mesa. The method of producing the power semiconductor device further comprises forming a plurality of first contacts electrically connecting the mesas; and forming a plurality of second contacts electrically connecting the trench electrodes; and forming at least one of the following: (i) a plurality of first spacer pairs, wherein each first spacer pair is associated with one of the mesas and arranged: above both the mesa and the trench electrodes adjacent to the mesa; adjacent to one of the first contacts electrically connecting the mesa; and between the trench insulators of the trenches adjacent to the mesa; and/or (ii) a plurality of second spacer pairs, wherein each second spacer pair is associated with one of the trench electrodes and arranged: above both the trench electrode and the adjacent mesas; adjacent to one of the second contacts electrically connecting the trench electrode; and between portions of the trench insulator isolating the trench electrode from the semiconductor body.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIGS. 1 and 3 both schematically and exemplarily illustrate a section of a horizontal projection of a power semiconductor device in accordance with one or more embodiments;

FIG. 2 schematically and exemplarily illustrates a section of a vertical cross-section of a power semiconductor device in accordance with one or more embodiments;

FIGS. 4(A)-(E) each schematically and exemplarily illustrate a section of a vertical cross-section of a power semiconductor device in accordance with one or more embodiments;

FIGS. 5-13 schematically and exemplarily illustrate, based on schematical and exemplary illustrations of sections of a vertical cross-section, a first process flow of a method of producing a power semiconductor device in accordance with one or more embodiments;

FIGS. 14-22 schematically and exemplarily illustrate, based on schematical and exemplary illustrations of sections of a vertical cross-section, a second process flow of a method of producing a power semiconductor device in accordance with one or more embodiments; and

FIGS. 23-30 schematically and exemplarily illustrate, based on schematical and exemplary illustrations of sections of a vertical cross-section, a third process flow of a method of producing a power semiconductor device in accordance with one or more embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z” herein.

The first conductivity type is opposite to the second conductivity type. In this specification, n-doped is referred to as “first conductivity type” while p-doped is referred to as “second conductivity type”. Alternatively, opposite doping relations can be employed so that the first conductivity type can be p-doped and the second conductivity type can be n-doped. A dopant dose may be defined as the integral over the dopant concentration of the atoms of the respective conductivity type within a respective doping region in a vertical direction Z. The dopant dose may be the amount of dopant implanted per area.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device that may be used within a power converter or a power supply. Thus, in an embodiment, such power semiconductor device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell, a monolithically integrated transistor cell, e.g., a monolithically integrated IGBT or MOSFET cell and/or derivatives thereof. Such diode/transistor cells may be integrated within a single chip. A plurality of such cells may constitute a cell field that is arranged within an active region of the power semiconductor device.

The term “blocking state” of the power semiconductor device may refer to conditions, when the power semiconductor is in a state configured for blocking a load current flow while an external voltage is applied. More particularly, the power semiconductor device may be configured for blocking a forward load current through the power semiconductor device while a forward voltage bias is applied. In comparison, the power semiconductor device may be configured for conducting the forward load current in a “forward conducting state” of the power semiconductor device while a forward voltage bias is applied. A transition between the forward blocking state and the forward conducting state may be controlled by a control electrode or, more particularly, a potential of the control electrode. Said electrical characteristics may, of course, only apply within a predetermined working range of the external voltage and the current density within the power semiconductor device. The term “forward biased blocking state” therefore may refer to conditions with the power semiconductor device being in the forward blocking state while a forward voltage bias is applied.

The term “power semiconductor device” as used in this specification intends to describe a power semiconductor device on a single chip with high voltage blocking and/or high current-carrying capabilities. In other words, such power semiconductor device is intended for high current, typically in the Ampere range, e.g., up to several ten or hundred Ampere, and/or high voltages, typically above 15 V, more typically 100 V and above, e.g., up to at least 400 V or even more, e.g., up to at least 3 kV, or even up to 10 kV or more, depending on the respective application.

For example, the term “power semiconductor device” as used in this specification is not directed to logic semiconductor devices that are used for, e.g., storing data, computing data and/or other types of semiconductor-based data processing.

For example, the power semiconductor device described below may be a single semiconductor chip and can be configured to be employed as a power component in a low-, medium-, and/or high voltage application.

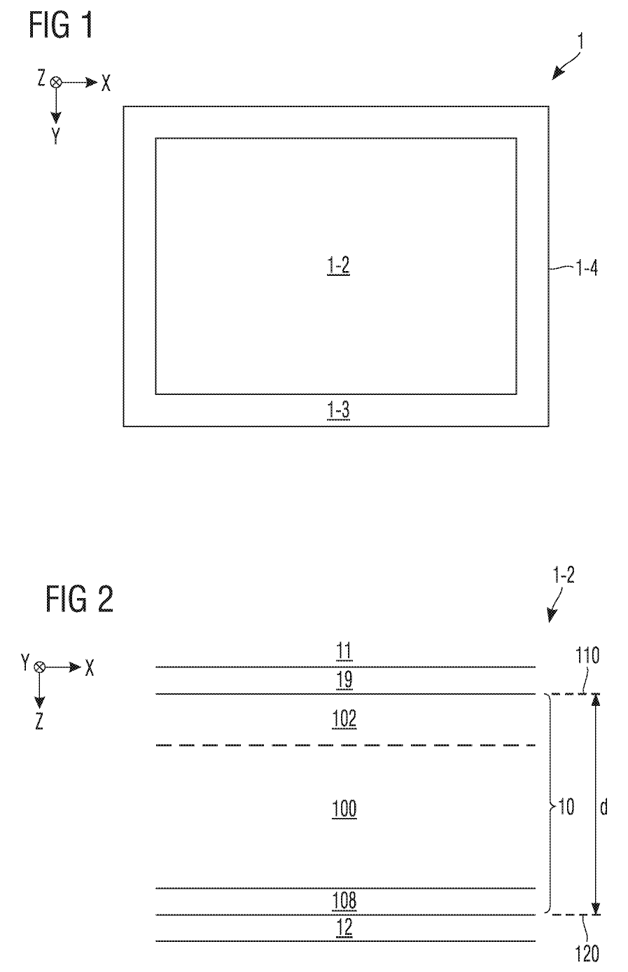

Reference will now be made to each of FIGS. 1 to 3 to describe some exemplary general features of a power semiconductor device 1 in accordance with one or more embodiments.

The power semiconductor device 1, herein also referred to as “device 1”, comprises, e.g., in a single chip, a semiconductor body 10 configured to conduct, in an active region 1-2, a load current between a first load terminal 11 at a front side 110 of the semiconductor body 10 and a second load terminal 12 at a back side 120 of the semiconductor body 10.

The device 1 can be, e.g., a diode, an IGBT (or a derivative thereof, such as RC IGBT) or, e.g., a MOSFET (or a derivative thereof). Accordingly, the first load terminal 11 may be an anode terminal, an emitter terminal or a source terminal, and the second load terminal 12 may be a cathode terminal, a collector terminal or a drain terminal.

As exemplarily illustrated in FIG. 1, the active region 1-2 of the device 1 is surrounded by an edge termination region 1-3. The edge termination region 1-3 is typically not employed for load current conduction, as it is known to the skilled person. The edge termination region 1-3 is terminated by a chip edge 1-4.

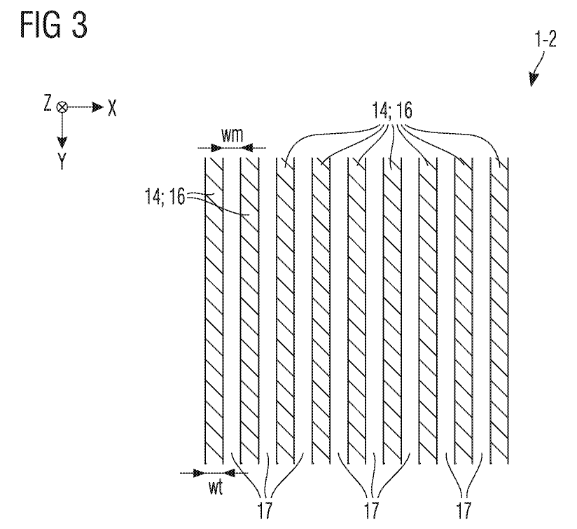

In the active region 1-2, a trench structure may form a cell field, e.g., in case of a diode, a MOSFET or an IGBT or a derivative of such a device configuration. For example, the device 1 exhibits, based on the trench structure, a stripe cell configuration, as exemplarily illustrated in FIG. 3. In other embodiments, the device 1 may exhibit a needle cell configuration or yet another cell configuration.

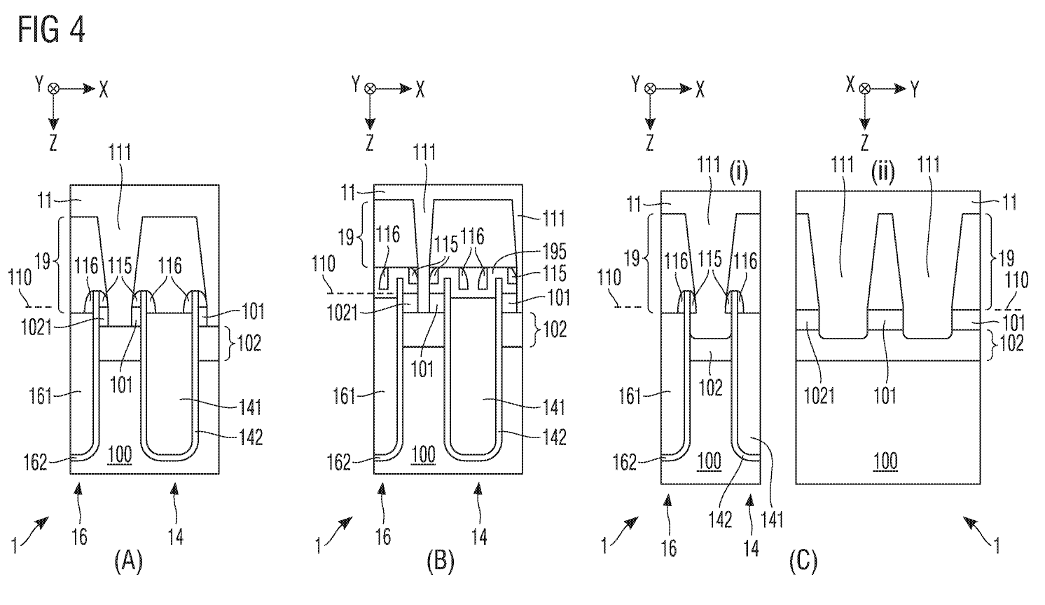

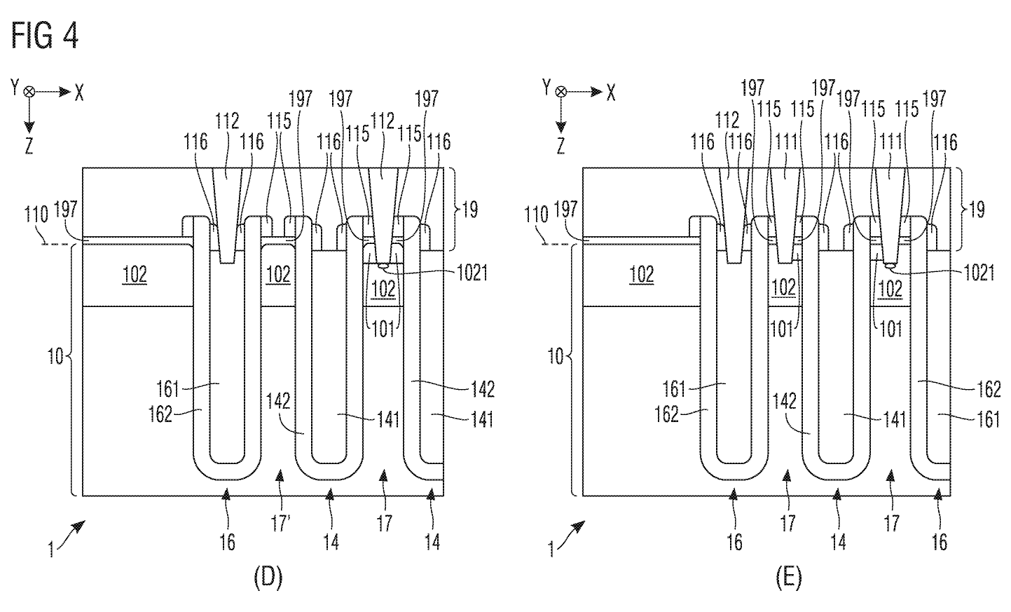

For example, as illustrated in FIG. 3, trenches 14 and 16 may extend along the second lateral direction Y through the active region 1-2, thereby laterally confining mesas 17 which are formed by portions of the semiconductor body 10 (cf. also FIGS. 4(A)-(E) .

The trenches 14, 16 may each exhibit a trench width wt along the first lateral direction X, wherein the trench width wt is for example within the range of 0.1 to 5 µm. The mesas 17 may each exhibit a mesa width wm along the first lateral direction X, wherein the mesa width wm is for example within the range of 0.1 to 5 µm. In the active region 1-2, each mesa 17 may exhibit the cell mesa width wm, and/or each trench 14, 16 may exhibit the same trench width wt.

As will become more apparent from the FIGS. 4(A) et seq., each trench 14, 16 may include a trench electrode 141, 161 and a trench insulator 142, 162 isolating the trench electrode 141, 162 from the semiconductor body 10.

For example, the trenches include control trenches 14, wherein each control trench 14 comprises a control trench electrode 141 and a control trench insulator 142, and wherein the control trench electrode 141 may be electrically connected to a control terminal. Further, if present, the control trench electrodes 141 must not necessarily each be connected with the same control terminal, but could also be connected to two or more different control terminals, such that the device 1 may be controlled based on more than one control signal, e.g., for realizing a dual-gate-configuration.

For example, the trenches may additionally or alternatively include source trenches 16, wherein each source trench 16 comprises a source trench electrode 161 and a source trench insulator 162, and wherein the source trench electrode 161 may be electrically connected to the first load terminal 11 or be electrically connected with another defined electrical potential or be electrically floating.

Further, cf. FIGS. 4(A)-(E) , a plurality of first contacts 111 may be provided for electrically connecting the mesas 17. A plurality of second contacts 112 may be provided for electrically connecting the trench electrodes 141, 161.

As exemplarily illustrated in FIG. 2, the front side 110 and the back side 120 may be arranged opposite of each other. Accordingly, the device 1 may exhibit a vertical configuration according to which the load current within the device 1 follows a path in parallel to the vertical direction Z. The semiconductor body 10 may be sandwiched between the first load terminal 11 and the second load terminal 12 and exhibit a vertical extension d, e.g., in the range of 40 µm to 750 µm, depending, e.g., on the maximal blocking voltage the device 1 shall exhibit.

The device 1 further comprises a drift region 100 of a first conductivity type within the semiconductor body 10. Herein, the term “drift region” is employed within the meaning the skilled person typically associates therewith in the field of power semiconductor devices. For example, the vertical extension of the drift region 100 influences the voltage blocking capabilities (e.g., said maximal blocking voltage) of the device 1.

As also schematically illustrated in FIG. 2, at the front side 110, the semiconductor body 10 may comprise a doped front side region 102 of the second conductivity type electrically connected to the first load terminal 11. E.g., the doped front side region is a body region in electrical contact with the first load terminal 11. To this end, said first contacts 111 may be employed.

Further, at the back side 120, a doped back side region 108 of the semiconductor body 10 may be provided below the drift region 100. The adjoining doped back side region 108 can be electrically connected with the second load terminal 12 and can be configured in accordance with the designated characteristic of the device 1. E.g., the doped back side region 108 can be a cathode region of the first conductivity type, if the device 1 shall exhibit a diode or MOSFET configuration. Or, the doped back side region 108 can be an emitter region of the second conductivity type, if the device 1 shall exhibit an IGBT configuration. If the device 1 shall exhibit an RC IGBT configuration, the doped region 108 can be an emitter region of the second conductivity type exhibiting subsections of the first conductivity type, as it is known to the skilled person. If the device 1 shall exhibit a MOSFET configuration, the doped back side region 108 can be a highly doped region of the first conductivity type adjoining the second load terminal 12. In any case, the doped back side region 108 can be arranged in contact with the second load terminal 12.

In addition, a (non-illustrated) field stop region of the first conductivity type can be provided between the drift region 100 and the doped back side region 108, wherein the field stop region exhibits a greater dopant concentration than the drift region 100.

Between the front side 110 and the first load terminal 11, there may be arranged a first insulation layer 19 such that the semiconductor body 10 is only locally electrically contacted with the first load terminal, e.g., based on said first contacts 111 arranged between the first load terminal 11 and the mesas 17 and penetrating the first insulation layer 19, as will be described in more detail in the following.

In accordance with the embodiment illustrated in FIG. 4(A), the device 1 further comprises a plurality of first spacer pairs 115, wherein each first spacer pair 115 is associated with one of the mesas 17 and arranged as follows: above both the mesa 17 and the trench electrodes 141, 161 adjacent to the mesa 17; adjacent to one of the first contacts 111 electrically connecting the mesa 17; and between the trench insulators 142, 162 of the trenches 14, 16 adjacent to the mesa 17.

In accordance with the embodiment illustrated in FIG. 4(D), which can be combined with the embodiment of FIG. 4(A), the device 1 further comprises a plurality of second spacer pairs 116, wherein each second spacer pair 116 is associated with one of the trench electrodes 141, 161 and arranged as follows: above both the trench electrode 141, 161 and the adjacent mesas 17; adjacent to one of the second contacts 112 electrically connecting the trench electrode 141, 161; and between portions of the trench insulator 142, 162 isolating the trench electrode 141, 161 from the semiconductor body 10.

For example, in accordance with the embodiment schematically illustrated in FIG. 4(A), the first contact 111 may extend from the first load terminal 11 along the vertical direction Z, thereby penetrate the first insulation layer 19 and extend between the first spacer pair 115 so as to electrically contact the mesa 17, e.g., both a highly doped portion 1021 of the doped front side region 102 (herein also referred to as body region 102) and a semiconductor source region 101 of the first conductivity type. The first contact 111 may extend below the first spacer pair 115. The first spacer pair may “sit” on the mesa 17 (i.e., the surface of the mesa 17) and extend above the adjacent trench electrodes 141 and 161.

In accordance with the embodiments schematically illustrated in FIGS. 4(A)-(E) , the first insulation layer 19 is arranged between, on the one side, the mesas 17 and the trench electrodes 141, 161 and, on the other side, the first load terminal 11, wherein the first contacts 111 and/or the second contacts 112 extend through the first insulation layer 19. In an embodiment, further insulation layers may be provided between, on the one side, the mesas 17 and the trench electrodes 141, 161 and, on the other side, the first load terminal 11.

For example, in accordance with the embodiment schematically illustrated in FIG. 4(B), the device 1 further comprises one or more intermediate insulation layers 195 arranged between, on the one side, the mesas 17 and the trench electrodes 141, 161 and, on the other side, the first insulation layer 19, wherein the first contacts 111 and/or the second contacts 112 extend through the at least one intermediate insulation layer 195, and wherein the first spacer pairs 115 and/or second spacer pairs 116 are arranged on top of the at least one intermediate insulation layer 195.

In an embodiment, the at least one intermediate insulation layer 195 includes at least one of tetraethyl orthosilicate, TEOS, silicon nitride, Si₃N₄, and silicon dioxide, SiO₂.

For example, based on the intermediate insulation layer 195, which may be thinner as compared to the first insulation layer 19, a distance along the vertical direction Z may be established between the first spacer pair 115 and the mesa 17, as apparent from a comparison of FIG. 4(A) and FIG. 4(B). Furthermore, based on the intermediate insulation layer 195, also a distance along the first lateral direction X may be established between the first spacer pair 115 and the trench insulators 142, 162, as also apparent from a comparison of FIG. 4(A) and FIG. 4(B). That is, in accordance with an embodiment, cf. e.g. FIG. 4(A), each first spacer pair 115 may be arranged in contact with the portions of the trench insulators 142, 162 that extend above the mesa 17, and/or each second spacer pair 116 may be arranged in contact with the portions of the trench insulator 142, 162 that extends above the trench electrode 141, 161. Or, in accordance with another embodiment, cf. e.g. FIG. 4(B), each first spacer pair 115 may be arranged laterally displaced from the portions of the trench insulators 142, 162 that extend above the mesa 17, and/or each second spacer pair 116 may be arranged laterally displaced from the portions of the trench insulator 142, 162 that extends above the trench electrode 141, 161.

In an embodiment, each of said portions of the trench insulators 142, 162 extending above both the trench electrodes 141, 161 and the mesas 17 do not laterally overlap with the trench electrode 141, 161. For example, an isolation of the top portions of the trench electrodes 141, 161 is established based on the first insulation layer 19 and/or based on the one or more intermediate insulation layers 195. That is, in accordance with an embodiment, the top portions of each trench electrode 141, 161 are not (or at most partially) covered by the trench insulators 142, 162. E.g., the trench insulators 142, 162 are based on an oxide. For example, said portions of the trench insulators 142, 162 extending above both the trench electrodes 141, 161 and the mesas 17 are based on (i) the same processing step(s) carried out for forming trench insulators 142, 162 not extending above both the trench electrodes 141, 161 and the mesas 17 and/or (ii) based on one or more separate processing steps.

In an embodiment, each of said top portions of the trench insulators 142, 162 extending above both the trench electrodes 141, 161 and the mesas 17 have approximately the same width as portions of the trench insulator 142, 162 which are in contact with the trench electrodes 141, 161. E.g. both type of portions are based on a single processing step, e.g., both type of portions are made from silicon oxide.

In another embodiment, the width of said top portions of the trench insulators 142, 162 extending above both the trench electrodes and the mesas 17 is altered and becomes different compared to the width of the portions of the trench insulator 142, 162 which are in contact with the trench electrodes 141, 161. Said top portions can be reduced in width (e.g., based on a back etch processing step) or increased in width (e.g., based on a deposition processing step, e.g., similar to the forming of the intermediate insulation layer 195), e.g., so as to laterally overlap with both the trench electrode 141, 161 and the mesa 17.

Whereas the trench insulators 142, 162 do, in an embodiment, not or at least not entirely cover the top sections of the trench electrodes 141, 161, portions 197 of an insulator may laterally extend, e.g., so as to cover the mesas 17 and/or further mesas 17’ that are not electrically connected to the first load terminal, cf. FIG. 4(D) ). Said insulator portions 197 can be a deposited layer, e.g., thinner than the trench insulators 142, 162, or an oxide layer that comes into being when also forming the trench insulators 142, 162, as will be described further below.

In accordance with an embodiment, cf. FIG. 4(C), illustration (i), each first contact 111 may overlap with at least 80% of the mesa 17 along a first lateral direction X, and/or each second contact 112 overlaps with at least 80% of the trench electrode 141, 161 along the first lateral direction X. Said overlap may even amount to 100%, as exemplarily illustrated in FIG. 4(C). In other embodiments, cf. e.g. FIG. 4(A), the width of the first contact 111 is kept significantly smaller than the width of the mesa 17, such that said overlap may amount to less than 80%.

Irrespective of the width of the first contact 111 relative to the mesa width, the first contact 111 may be laterally structured along the second lateral direction Y, cf. FIG. 4(C), illustration (ii). Likewise, each second contact 112 may be laterally structured along the second lateral direction Y. Accordingly, for example, each first contact 111 may be configured as a plurality of first contact plugs and the mesa 17 may be contacted by the first contact plugs spaced apart from each other along the second lateral direction Y. The same may apply for the second contacts 112, in accordance with an embodiment.

In each mesa 17, the semiconductor source regions 101 may be provided at both lateral sides of the first contact 111 (cf. FIG. 4(D)) or at only one lateral side of the first contact 111 (cf. FIG. 4(E)). Also, the highly doped portion 1021 of the body region 102 in contact with the first contact 111 can be arranged below the first contact 111 (cf. FIGS. 4(D) and 4(E)) and/or at a lateral side of the first contact 111 (cf. FIGS. 4(A)-(C)). In addition, if the first contact 111 entirely overlaps with the mesa 17 (cf. FIG. 4(C)), the semiconductor source region 101 is contacted on a lateral side of the first contact that is parallel to the first lateral direction X, whereas in other embodiments illustrated in FIG. 4, said side of the first contact 111 is in parallel to the second lateral direction Y. Also, a combination of both types of contacts between the first contact 111 and the semiconductor source region 101 is possible.

In accordance with one or more embodiments, the first spacer pairs 115 and/or the second spacer pairs 116 include silicon nitride, Si3N4, and/or silicon oxide, SiO2. Furthermore, each first spacer pair 115 may be arranged in contact with one of the first contacts 111, and/or each second spacer pair 116 may be arranged in contact with one of the second contacts 112. For example, the position of the first contacts 111 may be self-aligned with respect to the first spacer pairs 115, and the position of the second contacts 112 may be self-aligned with respect to the second spacer pairs 116. In addition, in accordance with an embodiment, each first spacer pair 115 does not overlap with the trench electrodes 141, 161 along the vertical direction Z, and/or each second spacer pair 116 does not overlap with the trench electrodes 141, 161 along the vertical direction Z. Accordingly, the first spacer pairs 115 adjacent to the mesas 17 may be arranged at the same, or at a lower, or at a higher level with respect to the vertical direction Z than the spacer pairs 116 adjacent to the trench electrodes 141, 161, as exemplarily shown in FIGS. 4(A),4(B) and 4(C) .

In an embodiment, the first spacer pairs 115 are isolated from and not in direct contact with trench electrodes 141, 161. Further, the second spacer pairs 116 are isolated from and not in direct contact with mesas 17.

Presented herein is also a method of producing a power semiconductor device.

For example, the method of producing a power semiconductor device comprises forming the following components: a semiconductor body including a drift region of a first conductivity type arranged between a front side and a back side of the semiconductor body; a first load terminal at the front side and a second load terminal at the back side, wherein the semiconductor body is configured to conduct a load current along a vertical direction between the first load terminal and the second load terminal; a plurality of trenches extending from the front side along the vertical direction into the semiconductor body; a plurality of mesas formed by portions of the semiconductor body laterally confined by the plurality of trenches. Each trench includes a trench electrode; and a trench insulator isolating the trench electrode from the semiconductor body, wherein a portion of the trench insulator extends above both the trench electrode and the adjacent mesa. The method of producing the power semiconductor device further comprises forming a plurality of first contacts electrically connecting the mesas; and forming a plurality of second contacts electrically connecting the trench electrodes; and forming at least one of the following: (i) a plurality of first spacer pairs, wherein each first spacer pair is associated with one of the mesas and arranged: above both the mesa and the trench electrodes adjacent to the mesa; adjacent to one of the first contacts electrically connecting the mesa; and between the trench insulators of the trenches adjacent to the mesa; and/or (ii) a plurality of second spacer pairs, wherein each second spacer pair is associated with one of the trench electrodes and arranged: above both the trench electrode and the adjacent mesas; adjacent to one of the second contacts electrically connecting the trench electrode; and between portions of the trench insulator isolating the trench electrode from the semiconductor body.

Some embodiments of the above-described method correspond to the embodiments of the power semiconductor device 1 described above. Accordingly, these embodiments of the method will not literally be described herein, but it is referred to the above. Likewise, aspects described with respect to exemplary methods below may apply to the embodiments of the device 1 described above.

With respect to FIGS. 5-30, three exemplary process flows in accordance with embodiments of the method shall be described. The reference numerals provided in these drawings designate the same parts as in the preceding drawings, such that the description provided above analogously applies for FIGS. 5-30.

Some of the vertical cross-sections illustrated in FIGS. 5-30 show both a section of the active region 1-2 and a section of the edge termination region 1-3. The edge termination region 1-3 may comprise one or more edge termination trenches 15, each having a trench electrode 151 and a trench insulator 152, wherein said trench electrodes 151 can for example be electrically connected with the first load terminal 11. For example, the edge termination trenches 15 extend into a doped deep region 105 of the second conductivity type electrically connected to the first load terminal 11.Between the doped deep region 105 and the chip edge 1-4, there may be arranged a doped ring region 106 of the second conductivity type. Both the doped ring region 106 and the doped deep region 105 may surround the active region 1-2. An insulation trench 198 may extend into the doped ring region 106 and also surround the active region 1-2.

Process flow A (FIG. 5-13)

In stage 200, cf. FIG. 5, the semiconductor body 10 is provided, wherein the trenches 14, 15 and 16, including the trench insulators 142, 152, 162 and the trench electrodes 141, 151, 162 as well as said insulator portion 197 have already been formed. For example, insulator portion 197 is a thin screening layer.

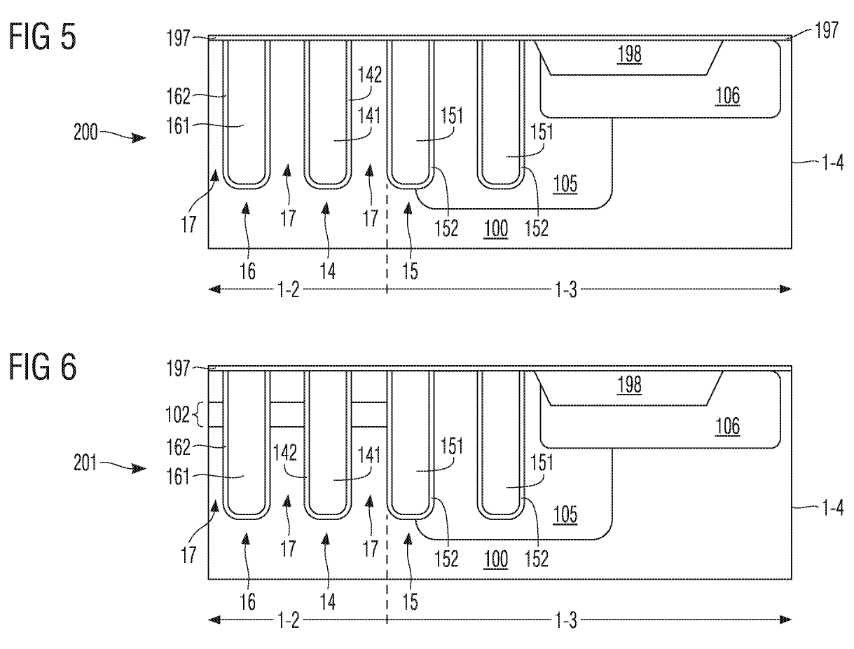

In stage 201, cf. FIG. 6, the body region 102 is formed, e.g., based on one or more implantation processing steps and a subsequent anneal processing step.

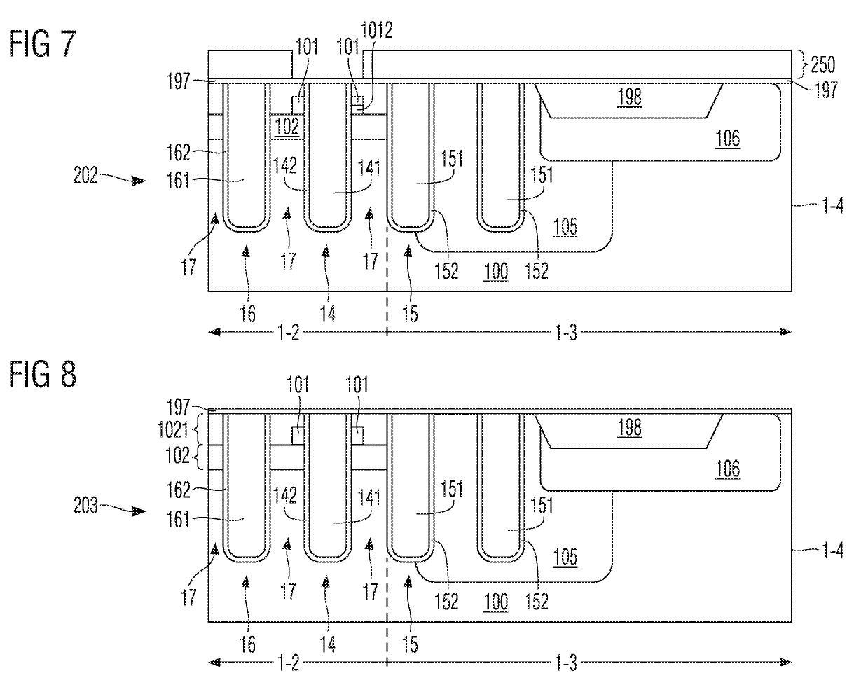

In stage 202, cf. FIG. 7, the semiconductor source regions 101 and, optionally, extension portions 1012 are formed (to reach the body region 102), e.g., based on one or more implantation processing steps and using a mask layer 250.

In stage 203, cf. FIG. 8, the highly doped portions 1021 of the body region 102 are formed, e.g., based on one or more implantation processing steps, e.g., not using a mask layer.

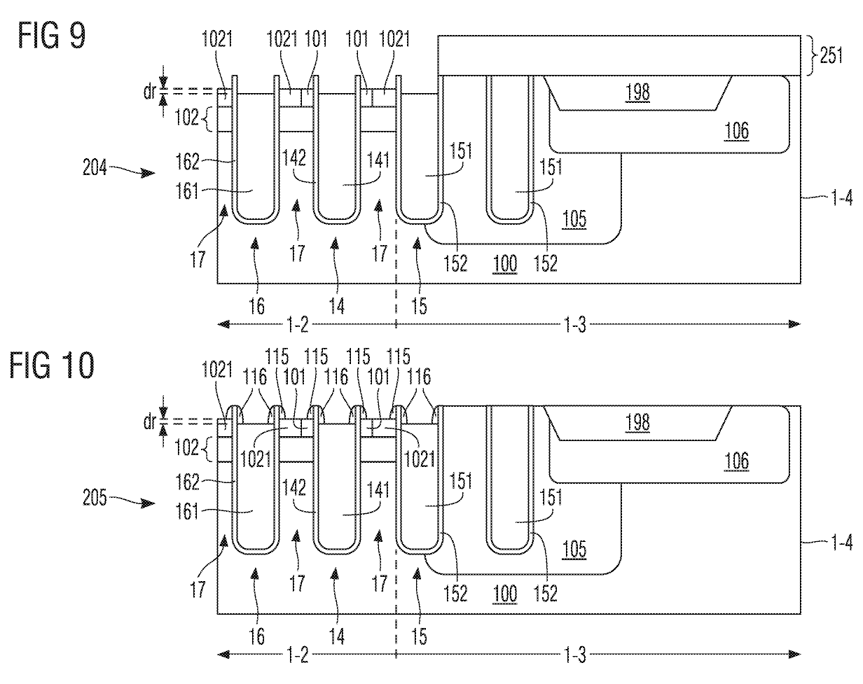

In stage 204, cf. FIG. 9, the insulator portion 197 is removed, and both top portions of the mesas 17 and the trench electrodes 141, 151 and 161 are recessed so as to form said portions of the trench insulator 142, 152, 162 extending above both the trench electrodes 141, 151, 161 and the adjacent mesas 17. Depending on the desired design of the device 1, a further mask layer 251 may be employed in regions where such recess shall not occur, e.g., in the edge termination region 1-3 or in a portion thereof. Further, the recess depths may differ between the mesas 17 and the trench electrodes 141, 151, 161; e.g., the recess of the trench electrodes 141, 151, 161 is slightly deeper, e.g., by a distance dr, as compared to the recess of the mesas 17. The distance dr may be within the range of 0 nm to 200 nm. For example, said distance dr may come into being due to different etch rates. Further, said distance dr may lead to a reduction of leakage currents.

In stage 205, cf. FIG. 10, the first spacer pairs 115 and the second spacer pairs 116 are formed. E.g., this stage includes carrying out one or more deposition processing steps and one or more anisotropic etch processing steps. In this embodiment, the first spacer pairs 115 are arranged on top of and in contact with the mesas 17, and the second spacer pairs 116 are arranged on top of and in contact with the trench electrodes 141, 151, 161.

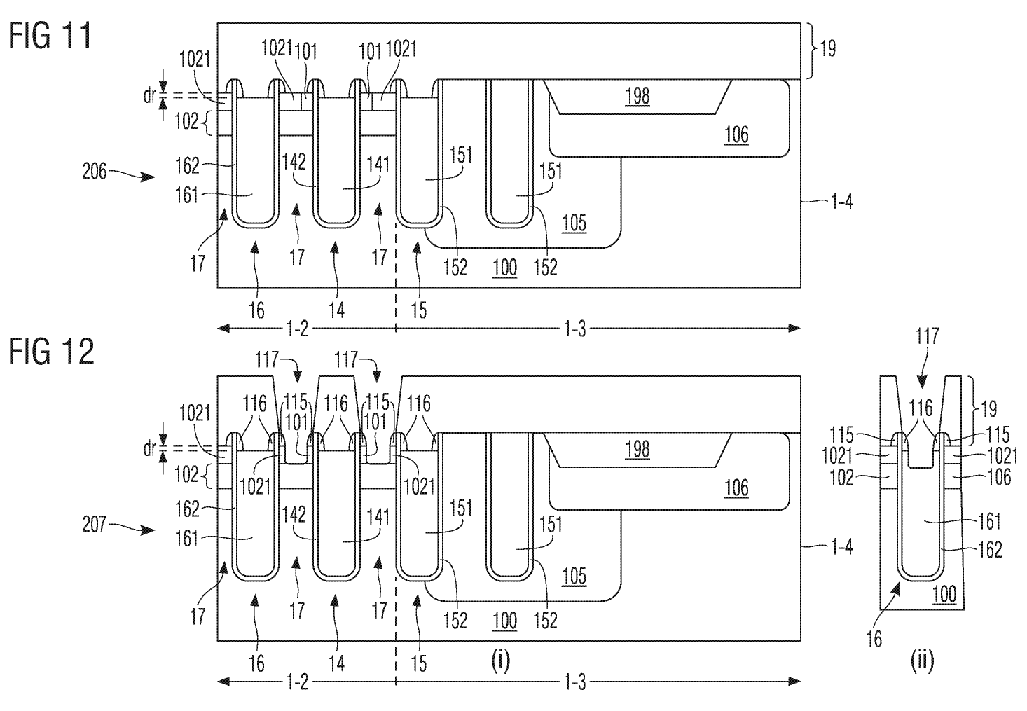

In stage 206, cf. FIG. 11, the first insulation layer 19 is formed, e.g., based on one or more deposition processing steps. The first insulation layer 19 may include Tetraethylorthosilicate, TEOS, and/or boron and phosphorus doped silicon oxide films, BPSG.

In stage 207, cf. FIG. 12, illustrations (i) and (ii), recesses 117 are formed within the first insulation layer 19, wherein the recesses 117 may later be filled with a conductive material to form the first contacts 111 and second contacts 112. This stage may include carrying out one or more etch processing steps, e.g., self-aligned with respect to the first spacer pairs 115 and/or the second spacer pairs 116. E.g., one or more etch processing steps are carried out for recessing the first insulation layer 19, and one or more etch processing steps are carried out for recessing the mesas 17 (e.g., to create a little groove within the mesas 17 such that first contacts may contact the semiconductor source region 101 and the highly doped section 1021 of the body region 102). In accordance with illustration (i) of FIG. 12, recesses are only formed for the first contacts 111, but the same processes could be applied to form recesses for the second contacts 112 for contacting the trench electrodes 141, 151, 161, cf. illustration (ii) in FIG. 12.

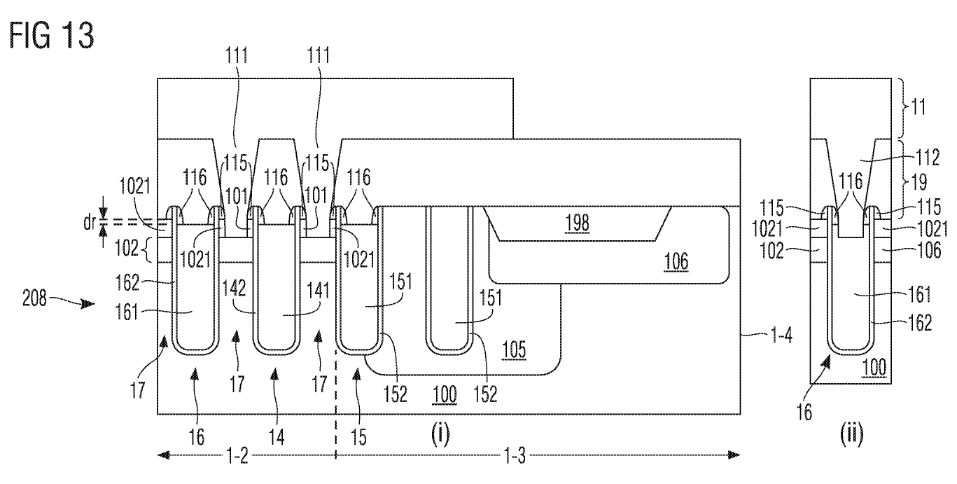

In stage 208, cf. FIG. 13, illustrations (i) and (ii), the first load terminal 11 and the first contacts 111 and the second contacts 112 are formed, e.g., by depositing a metal in the recesses 117 and on top of the first insulation layer 19 and, optionally, structuring the metal appropriately.

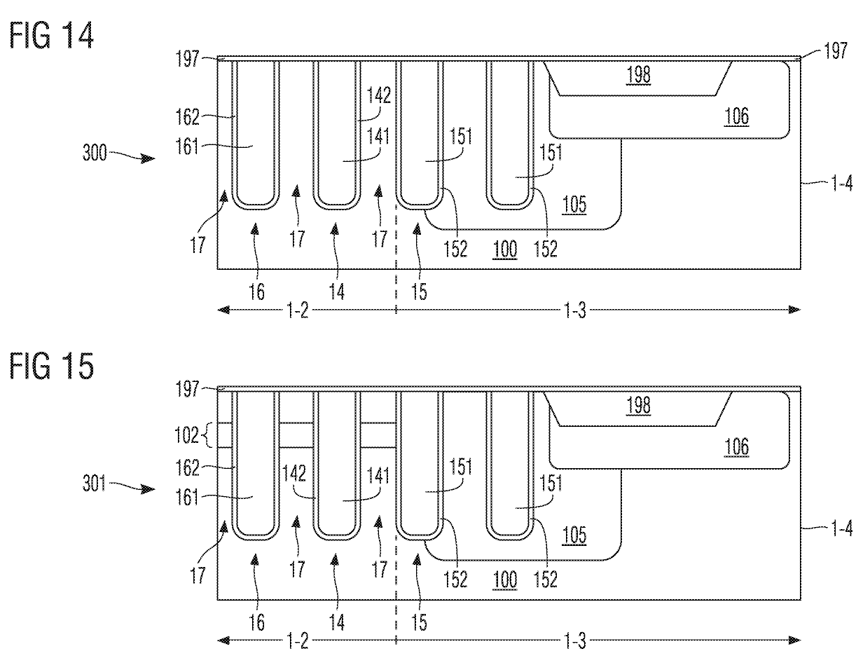

Process flow B (FIGS. 14-22)

In stage 300, cf. FIG. 14, the semiconductor body 10 is provided, wherein the trenches 14, 15 and 16, including the trench insulators 142, 152, 162 and the trench electrodes 141, 151, 162 as well as said insulator portion (e.g., screening layer) 197 have already been formed.

In stage 301, cf. FIG. 15, the body region 102 is formed, e.g., based on one or more implantation processing steps and a subsequent anneal processing step.

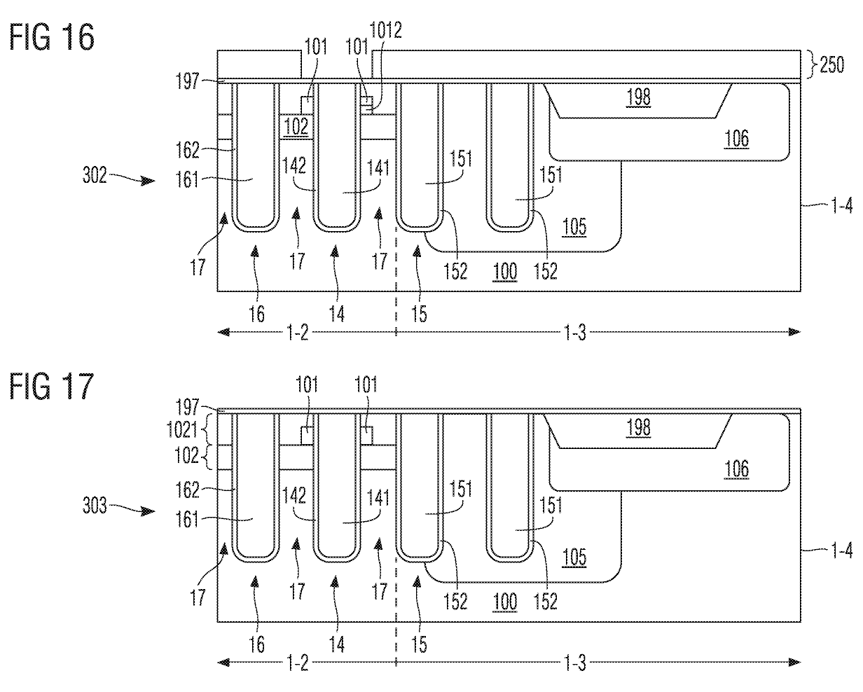

In stage 302, cf. FIG. 16, the semiconductor source regions 101 and, optionally, extension portions 1012 are formed (to reach the body region 102), e.g., based on one or more implantation processing steps and using a mask layer 250.

In stage 303, cf. FIG. 17, the highly doped portions 1021 of the body region 102 are formed, e.g., based on one or more implantation processing steps, e.g., not using a mask layer.

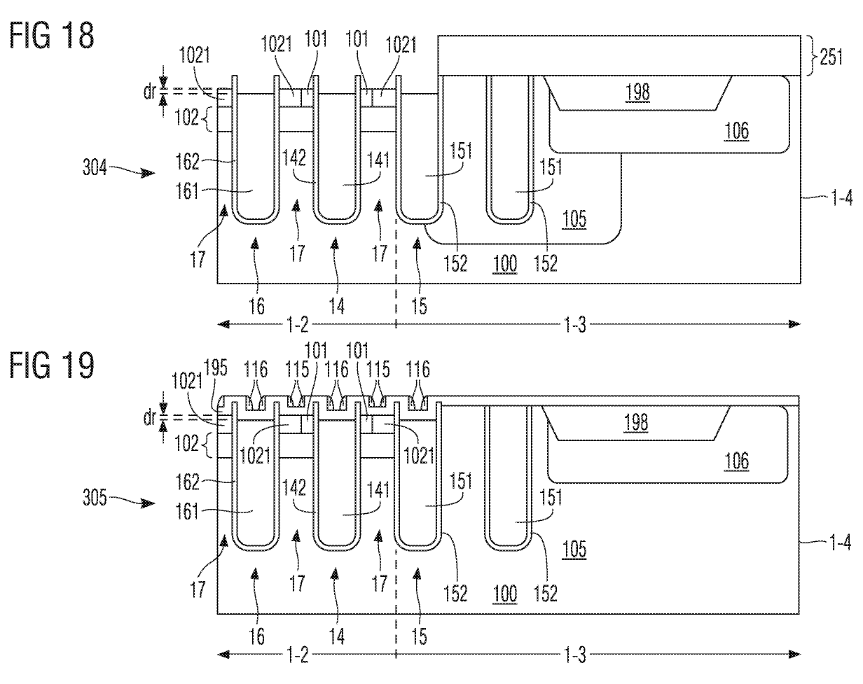

In stage 304, cf. FIG. 18, the insulator portion 197 (e.g., screening layer) is removed, and both top portions of the mesas 17 and the trench electrodes 141, 151 and 161 are recessed so as to form said portions of the trench insulator 142, 152, 162 extending above both the trench electrodes 141, 151, 161 and the adjacent mesas 17. Depending on the desired design of the device 1, a further mask layer 251 may be employed in regions where such recess shall not occur, e.g., in the edge termination region 1-3 or in a portion thereof. Further, the recess depths may differ between the mesas 17 and the trench electrodes 141, 151, 161; e.g., the recess of the trench electrodes is slightly deeper, e.g., by a distance dr, as compared to the recess of the mesas 17. The distance dr may be within the range of 0 nm to 200 nm. For example, said distance dr may come into being due to different etch rates. Further, said distance dr may lead to a reduction of leakage currents.

In stage 305, cf. FIG. 19, after the intermediate insulation layer 195 has been formed, e.g., based on one or more deposition processing steps, the first spacer pairs 115 and the second spacer pairs 116 are formed. E.g., forming the first spacer pairs 115 and the second spacer pairs 116 includes carrying out one or more deposition processing steps and one or more anisotropic etch processing steps. In this embodiment, the first spacer pairs 115 are arranged on top of and in contact with the intermediate insulation layer 195, and also the second spacer pairs 116 are arranged on top of and in contact with the intermediate insulation layer 195.

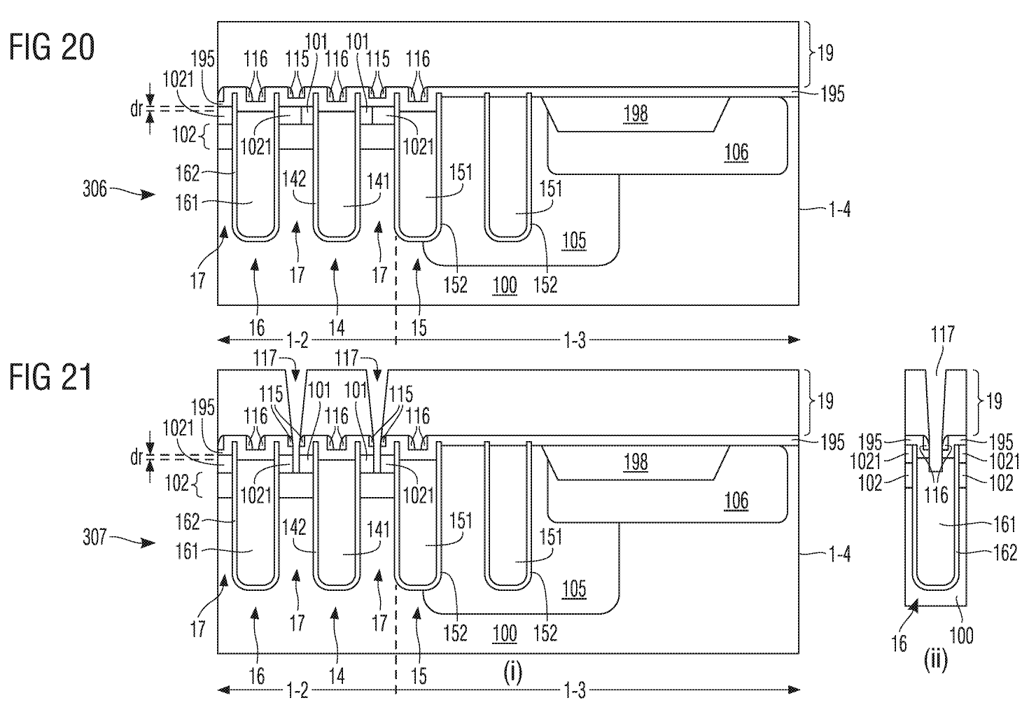

In stage 306, cf. FIG. 20, the first insulation layer 19 is formed, e.g., based on one or more deposition processing steps. The first insulation layer 19 may for example include boron and phosphorus doped silicon oxide films, BPSG.

In stage 307, cf. FIG. 21, illustrations (i) and (ii), recesses 117 are formed within the first insulation layer 19, wherein the recesses 117 may later be filled with conductive material to form the first contacts 111 and second contacts 112. This stage may include carrying out one or more etch processing steps, e.g., self-aligned with respect to the first spacer pairs 115 and/or the second spacer pairs 116. E.g., one or more etch processing steps are carried out for recessing the first insulation layer 19 and the intermediate insulation layer 195, and one or more etch processing steps are carried out for recessing the mesas 17 (i.e., to create a little groove within the mesas 17 such that first contacts may contact the semiconductor source region 101 and the highly doped section 1021 of the body region 102). In accordance with illustration (i) of FIG. 21, recesses are only formed for the first contacts 111, but the same processes could be applied to form recesses for the second contacts 112 for contacting the trench electrodes 141, 151, 161, cf. illustration (ii) in FIG. 21.

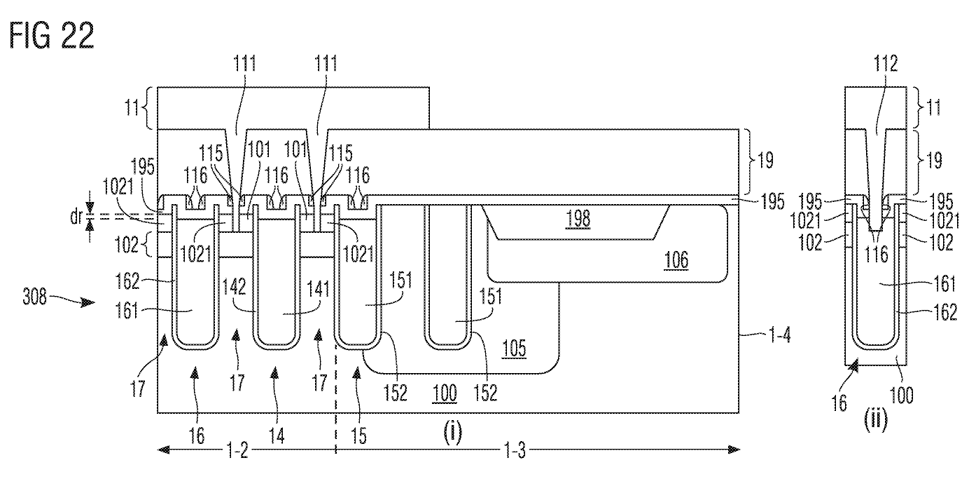

In stage 308, cf. FIG. 22, illustrations (i) and (ii), the first load terminal 11 and the first contacts 111 and the second contacts 112 are formed, e.g., by depositing a metal in the recesses 117 and on top of the first insulation layer 19 and, optionally, structuring the meatal appropriately.

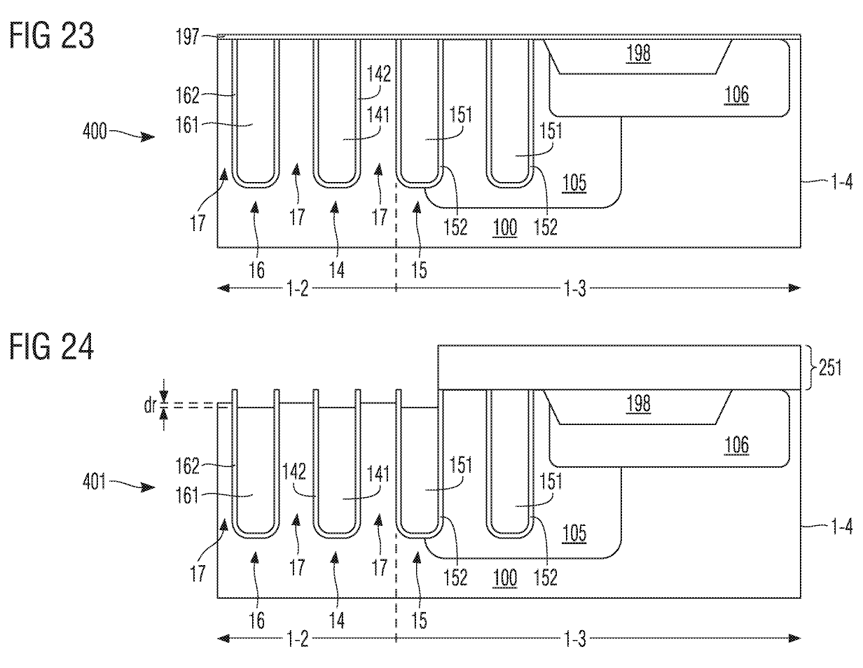

Process flow C (FIGS. 23-30)

In stage 400, cf. FIG. 23, the semiconductor body 10 is provided, wherein the trenches 14, 15 and 16, including the trench insulators 142, 152, 162 and the trench electrodes 141, 151, 162 as well as said insulator portion 197 (e.g., screening layer) have already been formed.

In stage 401, cf. FIG. 24, the insulator portion 197 is removed, and both top portions of the mesas 17 and the trench electrodes 141, 151 and 161 are recessed so as to form said portions of the trench insulator 142, 152, 162 extending above both the trench electrodes 141, 151, 161 and the adjacent mesas 17. Depending on the desired design of the device 1, a further mask layer 251 may be employed in regions where such recess shall not occur, e.g., in the edge termination region 1-3 or in a portion thereof. Further, the recess depths may differ between the mesas 17 and the trench electrodes 141, 151, 161; e.g., the recess of the trench electrodes is slightly deeper, e.g., by a distance dr, as compared to the recess of the mesas 17. The distance dr may be within the range of 0 nm to 200 nm. For example, said distance dr may come into being due to different etch rates. Further, said distance dr may lead to a reduction of leakage currents.

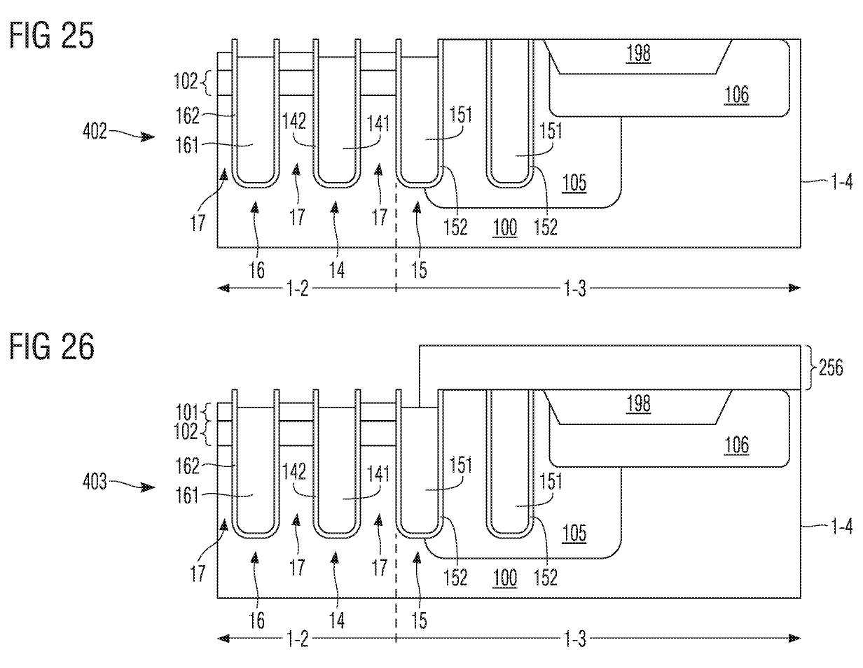

In stage 402, cf. FIG. 25, the body region 102 is formed, e.g., based on one or more implantation processing steps and a subsequent anneal processing step.

In stage 403, cf. FIG. 26, the semiconductor source regions 101 are formed, e.g., based on one or more implantation processing steps and using a mask layer 256. Here, the semiconductor source regions 101 exhibit the same widths as the mesas 17. In another embodiment, the semiconductor source regions 101 may be produced in accordance with process flow A or in accordance with process flow B as described above.

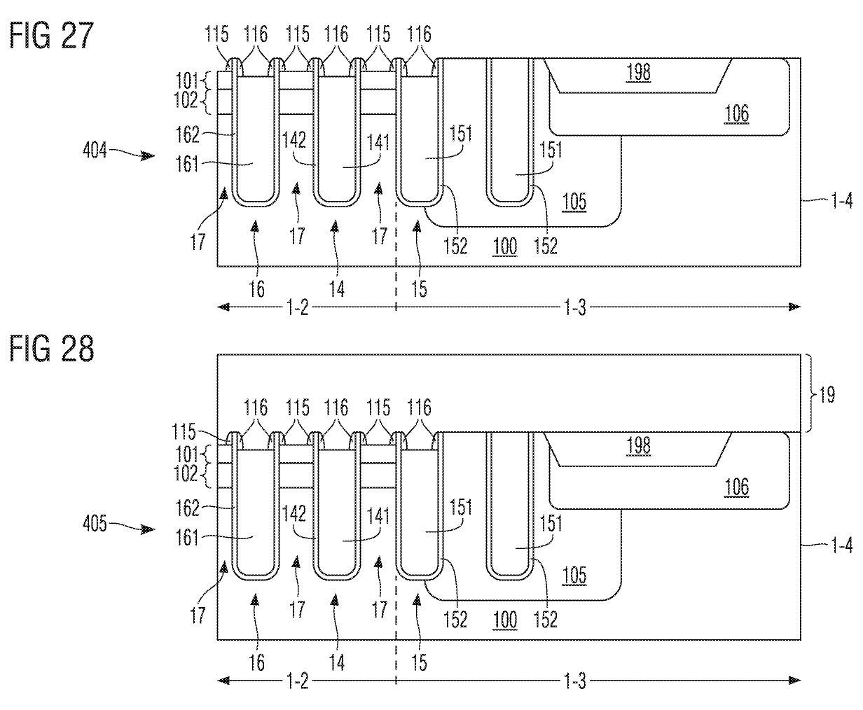

In stage 404, cf. FIG. 27, the first spacer pairs 115 and the second spacer pairs 116 are formed. E.g., forming the first spacer pairs 115 and the second spacer pairs 116 includes carrying out one or more deposition processing steps and one or more anisotropic etch processing steps. In this embodiment, the first spacer pairs 115 are arranged on top of and in contact with the mesas, and the second spacer pairs 116 are arranged on top of and in contact with the trench electrodes 141, 151, 161.

In stage 405, cf. FIG. 28, the first insulation layer 19 is formed, e.g., based on one or more deposition processing steps. The first insulation layer 19 may include Tetraethylorthosilicate, TEOS, and/or boron and phosphorus doped silicon oxide films, BPSG.

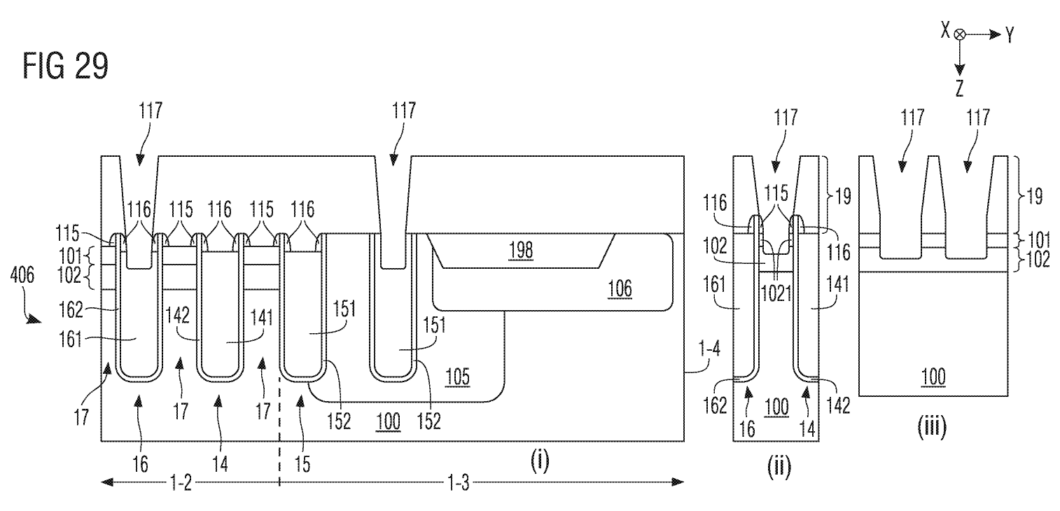

In stage 406, cf. FIG. 29, illustrations (i), (ii) and (iii), recesses 117 are formed within the first insulation layer 19, wherein the recesses 117 may later be filled with conductive material to form the first contacts 111 and second contacts 112. The stage may include carrying out one or more etch processing steps, e.g., self-aligned with respect to the first spacer pairs 115 and/or the second spacer pairs 116. E.g., one or more etch processing steps are carried out for recessing the first insulation layer 19, and one or more etch processing steps are carried out for recessing the mesas 17 (i.e., to create a little groove within the mesas 17 such that first contacts may contact the semiconductor source region 101 and the highly doped section 1021 of the body region 102). In accordance with illustration (i) of FIG. 29, recesses are only formed for the trench electrodes, but the same processes could be applied to form recesses for the first contacts 111 (for contacting the mesas), cf. illustrations (ii) and (iii) in FIG. 29. In this embodiment, each first contact 111 overlaps with at least 80% of the mesa 17 along a first lateral direction X. Further, the first contact 111 may be laterally structured along the second lateral direction Y, cf. FIG. 29, illustration (iii). That is, each first contact 111 may be configured as a plurality of first contact plugs and the mesa 17 may be contacted by the first contact plugs spaced apart from each other along the second lateral direction Y (corresponding to a “ladder contact”).

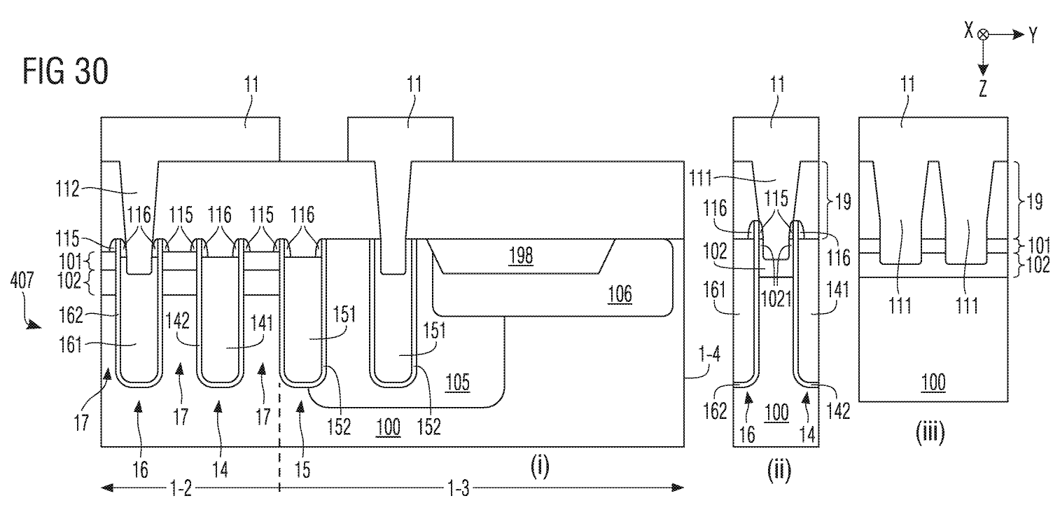

In stage 407, cf. FIG. 30, illustrations (i), (ii) and (iii), the first load terminal 11 and the first contacts 111 and the second contacts 112 are formed, e.g., by depositing a metal in the recesses 117 and on top of the first insulation layer 19 and, optionally, structuring the metal appropriately.

Regarding all embodiments described above, each of the intermediate insulation layer 195, the first space pairs 115 and the second spacer pairs 116 may be based on precursors (such as TEOS (Tetraethyl orthosilicate)), silicon oxide and/or silicon nitride layers, e.g., deposited based on processes such as LP-CVD (low-pressure chemical vapor deposition), PE-CVD (plasma-enhanced chemical vapor deposition) or ALD (atomic layer deposition).

Further, for each of the embodiments described above, the following may apply: a distance along the vertical direction Z between the top end of the trench insulator (cf. reference numeral 142, 152, 162) and the top end of the associated trench electrode (cf. reference numeral 141, 151, 161) may be within the range of 20 nm to 400 nm, e.g. in the range of 150 nm to 250 nm. Further, for each of the embodiments described above, the following may apply: a distance along the vertical direction Z between the top end of the trench insulator (cf. reference numeral 142, 152, 162) and the top end of the associated mesa (cf. reference numeral 17) may be within the range of …% to …% of the mesa width wm, or within the range of 20 nm to 400 nm, e.g. in the range of 150 nm to 250 nm. Said two distances may be identical to each other or deviate, e.g., by the difference dr, as explained with respect to FIGS. 9-13, 18-22 and 24.

In the above, embodiments pertaining to power semiconductor devices and corresponding production methods were explained.

For example, these power semiconductor devices are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that the semiconductor body and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)- aluminum gallium indium nitride (AlGaInN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixC1-x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms may refer to like elements throughout the description.

what is claimed is:

1. A power semiconductor device, comprising:
a semiconductor body including a drift region of a first conductivity type arranged between a front side and a back side of the semiconductor body;
a first load terminal at the front side and a second load terminal at the back side, wherein the semiconductor body is configured to conduct a load current along a vertical direction between the first load terminal and the second load terminal;
a plurality of trenches extending from the front side along the vertical direction into the semiconductor body;
a plurality of mesas formed by portions of the semiconductor body laterally confined by the plurality of trenches, wherein each trench includes a trench electrode and a trench insulator isolating the trench electrode from the semiconductor body, wherein a portion of the trench insulator extends above both the trench electrode and the adjacent mesa;
a plurality of first contacts electrically connecting the mesas;
a plurality of second contacts electrically connecting the trench electrodes; and
at least one of the following:
a plurality of first spacer pairs, wherein each first spacer pair is associated with one of the mesas and arranged:
above both the mesa and the trench electrodes adjacent to the mesa;
adjacent to one of the first contacts electrically connecting the mesa; and
between the trench insulators of the trenches adjacent to the mesa; and/or
a plurality of second spacer pairs, wherein each second spacer pair is associated with one of the trench electrodes and arranged:
above both the trench electrode and the adjacent mesas;
adjacent to one of the second contacts electrically connecting the trench electrode; and
between portions of the trench insulator isolating the trench electrode from the semiconductor body.

2. The power semiconductor device of claim 1, further comprising a first insulation layer arranged between, on a first side, the mesas and the trench electrodes and, on a second side, the first load terminal, wherein the first contacts and/or the second contacts extend through the first insulation layer.

3. The power semiconductor device of claim 2, further comprising one or more intermediate insulation layers arranged between, on the first side, the mesas and the trench electrodes and, on the second side, the first insulation layer, wherein the first contacts and/or the second contacts extend through the at least one intermediate insulation layer, and wherein the first spacer pairs and/or the second spacer pairs are arranged on top of the at least one intermediate insulation layer.

4. The power semiconductor device of claim 3, wherein the at least one intermediate insulation layer includes at least one of tetraethyl orthosilicate (TEOS), silicon nitride (Si₃N₄), and silicon dioxide (SiO₂).

5. The power semiconductor device of claim 1, wherein each first spacer pair is arranged in contact with the portions of the trench insulators that extend above the mesa, and/or wherein each second spacer pair is arranged in contact with the portions of the trench insulator that extends above the trench electrode.

6. The power semiconductor device of claim 1, wherein each first spacer pair is arranged laterally displaced from the portions of the trench insulators that extend above the mesa, and/or wherein each second spacer pair is arranged laterally displaced from the portions of the trench insulator that extends above the trench electrode.

7. The power semiconductor device of claim 1, wherein each of the portions of the trench insulators extending above both the trench electrodes and the mesas does not laterally overlap with the trench electrode.

8. The power semiconductor device of claim 1, wherein the top portions of each trench electrode are not covered by the trench insulators.

9. The power semiconductor device of claim 1, wherein the trench insulators are based on an oxide.

10. The power semiconductor device of claim 1, wherein each first contact overlaps with at least 80% of the mesa along a first lateral direction, and/or wherein each second contact overlaps with at least 80% of the trench electrode along the first lateral direction.

11. The power semiconductor device of claim 1, wherein each first contact is laterally structured along a second lateral direction, and/or wherein each second contact is laterally structured along the second lateral direction.

12. The power semiconductor device of claim 1, wherein the first spacer pairs and/or the second spacer pairs include silicon nitride (Si₃N₄) and/or silicon oxide (SiO₂).

13. The power semiconductor device of claim 1, wherein each first spacer pair is arranged in contact with one of the first contacts, and/or wherein each second spacer pair is arranged in contact with one of the second contacts.

14. The power semiconductor device of claim 1, wherein each first spacer pair does not overlap with the trench electrodes along the vertical direction, and/or wherein each second spacer pair does not overlap with the trench electrodes along the vertical direction.

15. The power semiconductor device of claim 1, wherein the first contacts are configured as first contact plugs, and/or wherein the second contacts are configured as second contact plugs.

16. A method of producing a power semiconductor device, the method comprising:
forming a semiconductor body including a drift region of a first conductivity type arranged between a front side and a back side of the semiconductor body;
forming a first load terminal at the front side and a second load terminal at the back side, wherein the semiconductor body is configured to conduct a load current along a vertical direction between the first load terminal and the second load terminal;
forming a plurality of trenches extending from the front side along the vertical direction into the semiconductor body;
forming a plurality of mesas from portions of the semiconductor body laterally confined by the plurality of trenches, wherein each trench includes a trench electrode and a trench insulator isolating the trench electrode from the semiconductor body, wherein a portion of the trench insulator extends above both the trench electrode and the adjacent mesa;
forming a plurality of first contacts electrically connecting the mesas;
forming a plurality of second contacts electrically connecting the trench electrodes; and
forming at least one of the following:
a plurality of first spacer pairs, wherein each first spacer pair is associated with one of the mesas and arranged:
above both the mesa and the trench electrodes adjacent to the mesa;
adjacent to one of the first contacts electrically connecting the mesa; and
between the trench insulators of the trenches adjacent to the mesa; and/or
a plurality of second spacer pairs, wherein each second spacer pair is associated with one of the trench electrodes and arranged:
above both the trench electrode and the adjacent mesas;
adjacent to one of the second contacts electrically connecting the trench electrode; and
between portions of the trench insulator isolating the trench electrode from the semiconductor body.

17. The method of claim 16, further comprising one or more recess processing steps to form the portions of the trench insulators that extend above the mesas.

18. The method of claim 16, further comprising one or more deposition processing steps and one or more etch processing steps to form the plurality of first spacer pairs and/or the plurality of second spacer pairs.

19. The method of claim 16, further comprising subjecting an insulation layer above the front side to one or more etch processing steps, wherein at least one of the one or more etch processing steps is self-aligned with respect to the first spacer pairs and/or the second spacer pairs.

20. The method of claim 16, further comprising one or more implantation processing steps to form, within the mesas, at least one of a semiconductor source region and a semiconductor body region.
